(19) United States
(12) Patent Application Publication
(10) Pub. No.: US 2013/0197851 A1
(43) Pub. Date: Aug. 1, 2013

(54) TEST CONTROLLER FOR 3D STACKED INTEGRATED CIRCUITS

(71) Applicant: Sudipta Bhawmik, Bridgewater, NJ (US)

(72) Inventor: Sudipta Bhawmik, Bridgewater, NJ (US)

(73) Assignee: QUALCOMM Incorporated, San Diego, CA (US)

(21) Appl. No.: 13/420,742

(22) Filed: Mar. 15, 2012

Related U.S. Application Data
(60) Provisional application No. 61/593,365, filed on Feb. 1, 2012.

(51) Int. Cl. G06F 19/00; G01R 31/317

(52) U.S. Cl. 702/118; 702/117

(57) ABSTRACT

Stacked IC devices (or 3D semiconductor devices) have two or more semiconductor devices stacked so they occupy less space than two or more conventionally arranged semiconductor devices. Access to test infrastructures of stacked ICs is provided, regardless of configuration, while using a reduced number of interface pins. A master test controller is provided in a base die and at least one slave test controller is provided in another die. The master test controller is coupled to a test data control (TDC) bus and is configured to broadcast test instructions, test data, and an ID of a slave test controller. The slave test controller is also coupled to the TDC bus, is configured to recognize the broadcast test instructions and test data addressed to the slave test controller, and responds to the instructions when the instructions are addressed to the slave test controller.

### CROSS-REFERENCE TO RELATED APPLICATION

This application claims the benefit under 35 U.S.C. §119(e) to U.S. Provisional Patent Application No. 61/593,365, entitled “Test Controller For 3D Stacked Integrated Circuits,” filed on Feb. 1, 2012, the disclosure of which is expressly incorporated by reference herein in its entirety.

### BACKGROUND

1. Field

The present disclosure generally relates to semiconductor device assembly and testing. More specifically, the present disclosure relates to testing stacked integrated circuits (ICs).

2. Background

Current technology employs stacked semiconductor chips (e.g., microprocessors, digital signal processors, etc.). A 3D semiconductor device (or stacked IC device) can contain two or more semiconductor devices stacked vertically on they occupy less space than two or more conventionally arranged semiconductor devices. Each IC layer may comprise functional blocks such as logic, memory and analog blocks. The stacked IC device is a single integrated circuit built by stacking silicon wafers and/or ICs and interconnecting them vertically so that they behave as a single device. In some cases the stacked IC device may have multiple cores.

In some 3D stacks, through-substrate vias (TSVs) create vertical connections through the body of the semiconductor device. As their name suggests, TSVs are generally substantially vertical interconnects used to make electrical connections through a semiconductor. TSVs may include a conducting core and an insulating sleeve contained in a semiconductor substrate. By using TSV technology, stacked IC devices can pack a great deal of functionality into a small footprint. This TSV technique is sometimes also referred to as TSS (Through Silicon Stacking). TSVs are also referred to as through-silicon vias. With TSVs, critical electrical paths through the device can be drastically shortened, reducing capacitance and resistance and therefore improving power dissipation, and performance.

As die stacks become more complicated and are used more, issues of failure are presented. For 3D chip integration, if a good die is stacked with a bad die, the whole stack would be bad. Ensuring that a die and the stack are good is important. Like all ICs, these 3D stacked ICs are tested for manufacturing defects. Conventional test solutions include boundary scan testing, and require control and observation of special design-for-testability (DfT) features or circuitry.

Traditionally, 3D stacked ICs are difficult to test because upper tier structures are not exposed after bonding of the ICs. However, the test infrastructure on each die within a 3D stacked IC should be accessible and controlled during pre-bond and post-bond testing. Generally, this testing is accomplished with extra interface pins and/or probes dedicated solely to testing. It is desirable, however, to reduce the number of interface pins on the dies because each pin occupies valuable space.

### SUMMARY

According to one aspect of the present disclosure, an apparatus for testing a multiple component integrated circuit (IC) is described. The apparatus includes a master test controller, within one of the components, and coupled to a test data control (TDC) bus. The master test controller is configured to broadcast test instructions, test data, and an ID of a slave test controller. The apparatus further includes at least one slave test controller, within another one of the components, and coupled to the TDC bus. This slave test controller is configured to recognize the broadcast test instructions and test data addressed to the slave test controller, and to respond to the instruction when the instruction is addressed to the slave test controller.

In another aspect, a method of testing a multiple component integrated circuit (IC) is described. The method includes broadcasting test instructions, test data, and an ID of a slave test controller. The method further includes broadcasting a response to the test instruction when the broadcast ID matches the ID of the slave test controller.

In a further aspect, an apparatus for testing a multiple component integrated circuit (IC) is described. The apparatus includes means for broadcasting test instructions, test data, and an ID of a slave test controller, from a master test controller, within one of the components. The apparatus further includes means for broadcasting a response to the instruction when the broadcast ID matches an ID of the slave test controller.

According to another aspect, a method of testing a multiple component integrated circuit (IC) is described. The method includes the step of broadcasting test instructions, test data, and an ID of a slave test controller. The method further includes the step of broadcasting a response to the test instruction when the broadcast ID matches the ID of the slave test controller.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. it is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 is a conceptual diagram of a 3D stacked IC, according to one aspect of the present disclosure.

FIG. 2 is a conceptual diagram of an exemplary master test controller in one configuration of a testing apparatus according to the disclosure.

FIG. 3 is a state diagram of a master test controller, according to one aspect of the present disclosure.

FIG. 4 is a conceptual diagram of an exemplary slave test controller in one configuration of a testing apparatus according to the disclosure.

FIG. 5 is a state diagram of a slave test controller, according to one aspect of the present disclosure.

FIG. 6 is a block diagram illustrating a method for testing multiple components of an integrated circuit, according to one aspect of the present disclosure.

FIG. 7 is a block diagram showing an exemplary wireless communication system in which a configuration of the disclosure may be advantageously employed.

FIG. 8 is a block diagram illustrating a design workstation for circuit, layout, and logic design of a semiconductor component according to one aspect of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Configurations of the present application provide solutions that allow access to test infrastructures of stacked ICs, regardless of whether they are connected in serial, multi-drop, or star configurations, while using a reduced or minimal number of interface pins or pads. In other words the test control desitzn is agnostic and may function in any configuration. For example, in some configurations two interface pads may be utilized. Additionally, a base die, not the remaining upper tier dies, would have the space consuming connection pads.

The present disclosure uses a master test controller in a base die and multiple slave test controllers in the other dies. Furthermore, the master test controller may receive its inputs via traditional testing interfaces, such as TAP (test access port), or a processor interface. These configurations may provide simpler timing closures between dies, compared to daisy chained serial shift controllers used in IEEE 1149.1 or 1500. In addition, the configurations discussed herein support pre-bond, post-bond partial stack, and final packaging testing.

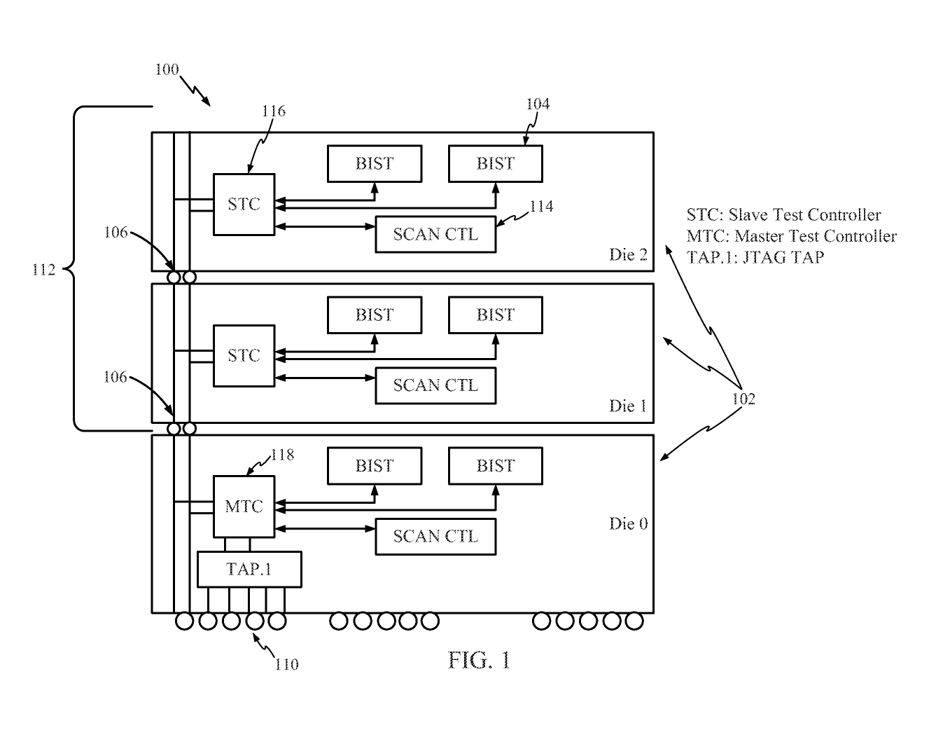

FIG. 1 shows a conceptual cross-sectional view illustrating a 3D stacked integrated circuit (IC) 100. Representatively, the IC 100 includes bond pads 110, multiple stacked dies 102, and interconnects 106. Though only two interconnects are used in this configuration, it is understood that any number of interconnects may be used. Each die may include multiple cores (not shown). The interconnects 106 may be tier to tier connections and TSVs, including portions within the die but shown as exposed for ease of viewing. Each of the dies 102 includes built in self test (BIST) modules 104. Built in self test modules 104 are hardware and. software features within integrated circuits, which allow self testing. Each of the dies 102 also include a scan controller 114 and a test controller 116, 118. The base die includes a master test controller (MTC) 118, whereas the upper tier dies 112 include slave test controllers (STCs) 116.

The master test controller 118 broadcasts command and control data to the slave test controllers 116 on the upper tiers 112. In some configurations, this occurs over a two pin interface. The two pin interface may be a single bit test data control (TDC) bus and a test clock (TCK) bus. A two pin interface allows for a reduced number of TSVs and pre-bond test pads. The test clock may run at higher speeds than traditional TAP TCKs.

Each controller has a unique ID of ‘n’ bits. In some configurations, the master test controller ID is all “1”s. When sending instructions on the test data control bus, the ID of the controller the instructions are meant for is included. Thus, when a controller recognizes that its ID is a match, the controller reads the instruction. The master test controller can therefore broadcast test control and/or data packets to the slave test controllers, and vice versa. In some configurations, the test control and data packets may include the controller ID, instructions (INST) and the control information or data for performing the instructions. The master test controller can be controlled from a TAP (Test Access Port) or a processor interface. In configurations where testing of an upper tier die occurs pre-bonding, the tester can implement the master test controller functions.

Though FIG. 1 shows one base die coupled to two upper tier dies, it is understood that any number of upper tier dies may be present. Furthermore, the upper tier dies may be coupled in any configuration including serially, multi-drop, or in a star configuration. Also, though one slave test controller is shown in each upper tier, each upper tier may have multiple slave test controllers. In addition, aspects of the disclosure also allow for configuration of internal logic testing as well as testing of the tier to tier interconnects. Other configurations of this disclosure further allow communication of this test data. Also, aspects of this disclosure may test multiple cores within a multi core die.

In aspects of the disclosure, the test controllers, whether master or slave, are to be accessible in pre-bond, post-bond partial stack and post-bond final or package testing. The controllers should use a reduced number of interface pins to decrease the number of probe pads used for pre-bond testing and reduce the number of TSVs for post-bond testing. The test controllers should be accessible in any configuration. The functionality of the controllers should not be dependent on stack configurations or the order of stacking. In some aspects, the controllers may not provide test data access (e.g. Scan/ATPG vectors), providing, instead, static control signals from register bits, without providing dynamic test controls (e.g., scan-enable).

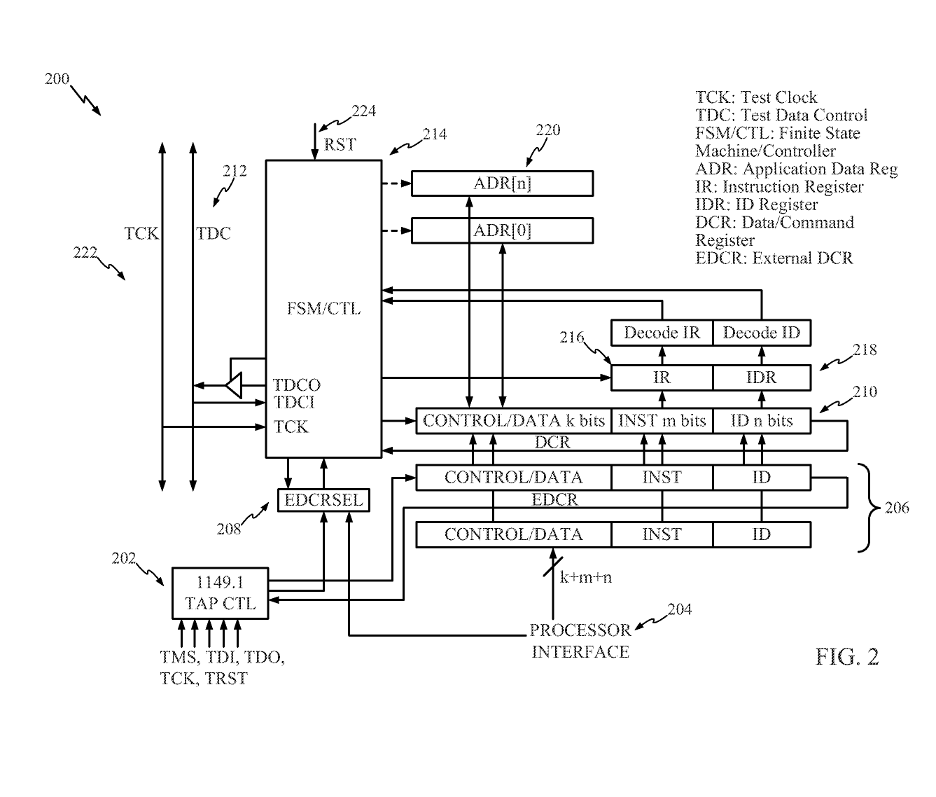

FIG. 2 shows a conceptual diagram of an exemplary master test controller 200 in one configuration of a testing apparatus. The master test controller 200 is implemented in the base die and may be accessed by either a traditional testing interface 202 or by a processor interface 204. Traditional testing interfaces or control mechanisms include standard test control methods, such as, IEEE 1149.1 JTAG or IEEE 1500.

Both interfaces 202, 204 couple to the external data command register (EDCR) 206 and the external data command register select (EDCRSEL) 208. Signalling from the external data command register select (EDCRSEL) 208, to the finite state machine controller (FSM/CTL) 214, begins the testing process. The master test controller 200 then communicates with the slave test controllers via the test data control (TDC) bus 212 and the test clock (TCK) bus 222.

The external data command register 206 is loaded with the ID of the controller being instructed, the instruction (for example, read or write), and the control information or data pertaining to the instruction. The external data command register 206 loads these values, from either interface 202, 204. These values are transferred into the master test controller data command register (DCR) 210 during the appropriate machine state. The data command register 210 forwards the instruction bits, and ID bits to an instruction register 216, and ID register 218, respectively, which decode the instruction and ID, triggering the proper finite state machine state. In some configurations the data command register 210 may be a fixed size register. The control information and data in the data command register 210 may then be shifted to the test data control bus 212, along with the instruction bits and ID. The test data control bus 212 then transmits the ID, instruction bits, control information and data to the slave test controllers.

The master test controller also may include application data registers 220 (ADRs). Application data registers (ADR) 220 in the master test controller can be accessed via TAP. In one example, a read instruction to a slave test controller would refer to a specific ADR in the slave test controller and in the master test controller. Application data registers 220 correspond to one or more test application infrastructures within the dies. For example, an ADR(0) may correspond to a built in self test controller in an upper tier die, or may be shared by all the built in self test controllers in the upper tiers. Therefore, when the master test controller sends out a read instruction to a slave test controller in, an upper tier die to read the contents of the built in self test controller, the slave test controller passes the contents of the corresponding application data register (for the built in self test controller in the specific upper tier die) to the master test controller via the test data control bus. The master test controller reads the data into the data command register and then passes the data to the corresponding application data register in the master or base die. The contents of the application data register in the master test controller can then be transferred to a TAP controller by using the application data register as a test data register of the TAP. In some aspects, the application data register function can be served by the external data command register as well.

Data transferred to the test data control bus 212 passes through the data command register 210. All transfers between an application data register 220 and the test data control bus 212 are through the data command register 210. The data command register 210 receives values from the application data register 220, couples this data with the ID and instruction data and shifts it out to the test data control bus 212. In a receiving controller, bits are received in the respective data command register from the test data control bus, from which the control/data section is transferred to the appropriate application data register based on the instruction.

The master test controller includes a reset (RST) pin 224. The reset pin 224 can be asserted by the chip reset (e.g., during power-up).

Information is loaded from and onto the TDC bus 212 via a test data control input (TDCI), and a test data control output (TDCO), respectively. The TCK bus 222 provides the test clock (TCK) to the finite state machine/controller 214.

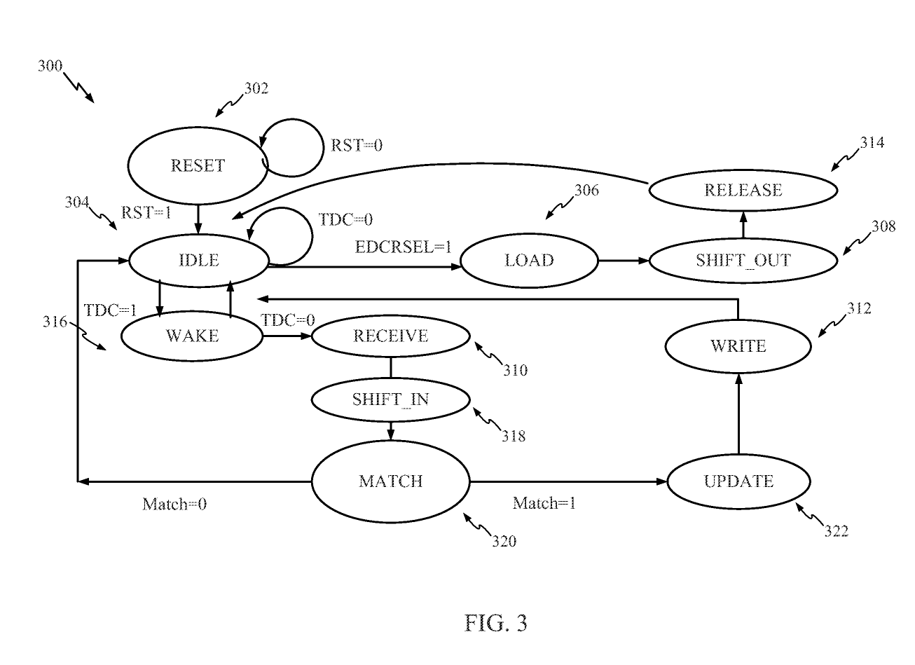

FIG. 3 is an exemplary state diagram of the master test controller. The master test controller enters a reset state 302 when reset is low (e.g., during power-up). In the reset state 302, the master test controller writes a “0” to the test data control bus, which is retained by a bus keeper. The master test controller enters an idle state 304 from the reset state 302 when reset is high. Loading information via one of the testing interfaces, traditional (TAP) or processor, triggers the EDCRSEL to high. Once EDCRSEL is high, the master test controller enters a load state 306, loading information in the data command register (DCR) from the corresponding external data command register(EDCR). Subsequently, the master test controller enters a shift-out/transmit state 308 to transmit the command and instruction (ID, INST, Control/Data) on the test data control (TDC) bus, which sends instructions to the slave test controllers. After completing the shift_out state 308, the master test controller enters the release state 314 to release the test data control bus in the next clock cycle, triggered by the test clock (TCK).

In some configurations, the master test controller includes two external data command registers. One for the traditional or TAP interface, which generally runs in serial and may have reduced speeds. Another external data command register is for the processor interface, which generally runs in parallel and may have increased speeds compared to that of the traditional interface. Once the data command register is loaded, the master test controller can decode the information, sending the controller into the proper state. After the external data command register is loaded, the EDCRSEL is reset to “0”.

Upon receiving information from the test data control bus, i.e., TDC=1, the master test controller awakens 316. The master test controller moves to a receive state 310 if TDC=0 or reverts back to an idle state 304 if the TDC stays at 1 during the clock cycle following the wake state 316. In a receive state 310, the master test controller behavior is similar to the behavior of a slave test controller. The received information is shifted into a register, in the shift_in state 318. The control/data, instruction and ID are all moved to the data command register from the TDC bus during the shift_instate 318. Next, in a match state 320, it is determined whether the ID matches the ID of the master test controller. If the ID is not a match (i.e., match=0) for the current controller, the controller reverts to the idle state 304. If the ID is a match (i.e., match=1) the master test controller moves to the update state 322 and begins processing the received information/data. The update state 322 loads the instruction and ID information to the instruction register (IR) and the ID register (IDR). In the next clock cycle the master test controller moves to the write 312 state. No other external trigger is necessary to transition to the write state 312. When in a write state 312, the master test controller writes all slave test controller ADR values received from a slave test controller into a single ADR on the master test controller or to specific ADRs for each slave test controller ADR. The ADR data can then be read by the TAP controller. After the master test controller finishes writing the values from the control/data segment to the corresponding application data register (ADR), a single clock cycle operation, the master test controller moves to the idle state 304 in the following clock cycle.

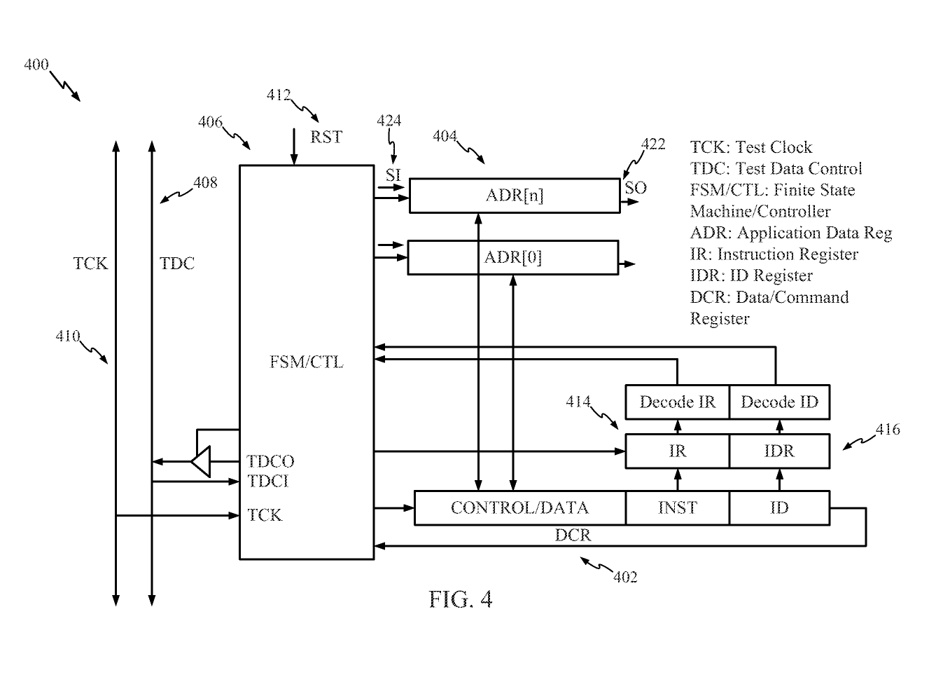

FIG. 4 shows a conceptual diagram of an exemplary slave test controller 400 in one configuration of a testing apparatus according to the disclosure. The slave test controller 400 is implemented in upper tier dies and therefore compatibility with JTAG (IEEE 1149.1) and processor interfaces is not included. That is, the base die master test controller cooperates with these testing interfaces and the master test controller then communicates with the slave test controller.

Each slave test controller 400 can communicate directly with the master test controller. In some configurations, the slave test controller 400 is similar to the master test controller; however, it is simpler because it does not include the external data command register (EDCR) or related components. Similar, to the master test controller, a data command register 402 (DCR) consists of an ID field (n bits), instruction (INST) field (m bits), and a control/data field (k bits). In some aspects, the instructions can include read from, write to, or write shift to a specific application data register 404 (ADR).

Information from the control/data field of the data command register can be written to an application data register 404, or an application data register value can be read into the data command register control/data field. The application data register 404 consists of test control bits or test status bits. Each application data register 404 has a serial in (SI) port 424 and a serial out (SO) port 422 for reading from and to, respectively, test control register(s) (e.g., a built in self test control register 104 (see FIG. 1).

The finite state machine/controller 406 (FSM/CTL) block reads or writes ID, instruction and control/data from and to the test data control bus 408 (TDC). An action, such as read or write, is performed by the slave test controller only if its ID matches the ID broadcast by the master test controller via the test data control bus 408 (TDC). The master test controller communicates with the slave test controllers via the test data control bus 408 (TDC) and the test clock (TCK) bus 410. When the slave test controller 400 receives a sequence of data via the test data control bus 408, the slave test controller 400 loads this data to the data command register 402.

The slave test controller 400 may also include an instruction register (IR) 414, ID register (IDR) 416, and application data registers (ADRs) 404. The ID register 416 compares the ID value in the data command register 402 with the slave controller ID and signals the slave test controller if it is a match. The IR register 414 decodes the instruction loaded in the instruction register 414 to determine whether the instruction is a read, write or write shift instruction and passes that information to the finite state machine controller 406. The slave test controller 400 includes a reset (RST) pin 412. The reset pin 412 can be asserted by the chip reset (e.g., during power-up).

Information is loaded from and onto the TDC bus 408 via a test data control input (TDCI), and a test data control output (TDCO), respectively. Data is received from the TCK bus 410 via a test clock (TCK) interface within the finite state machine/controller 406.

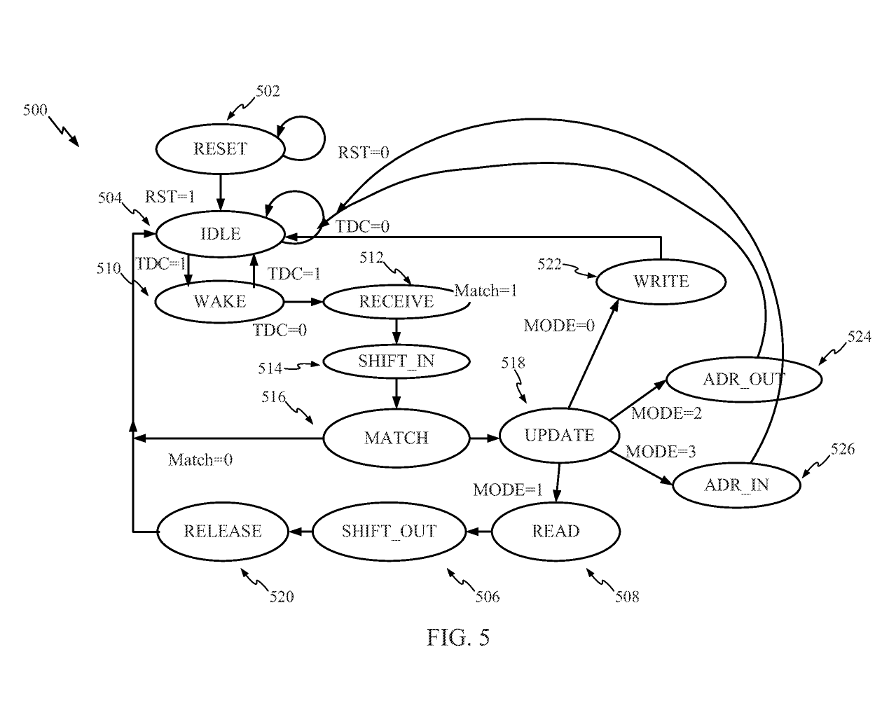

FIG. 5 shows an exemplary state diagram of the slave test controller. Generally, a slave test controller is a simplified version of a master test controller, functioning without an external data command register or EDCRSEL. The slave test controller enters a reset state 502 when reset is low (e.g., during power-up). The reset value can be shared with the system reset pin.

The master test controller releases the test data control bus after broadcasting the entire control/data packet with a weak “0” on the test data control bus. The slave test controller enters the idle state 504 from the reset state when reset is high (1) and the test data control value is low (0). The controller transitions to a wake state 510 when the test data control value is high (1). As described with relation to the master test controller, the slave test controller transitions from idle 504 to wake 510 when the TDC transitions from 0 to 1. From the wake state 510 the slave test controller moves to the receive state 512 if TDC=0, or back to idle 504 if TDC=1. Note, all state transition occur with a clock (TCK) transition. All slave test controllers traverse the state diagram in lock step until an ID match occurs to the ID transmitted via the test data control bus.

In the receive state 512, the master test controller and slave test controllers have similar behavior. The received information (including the ID, instruction and control/data) is shifted into a data command register, in the shift_in state 514. Next, in the match state 516 it is determined whether the ID information matches the current device, in this case the slave controller. If the ID is not a match (i.e., match=0) for the current controller, the controller reverts to the idle state 504. If the ID is a match (i.e., match=1), the slave test controller begins processing the remainder of the data. During the update state 518 the Instruction Register (IR) is loaded. The slave test controller proceeds to the remaining states, reading the instruction (read/write) and proceeding accordingly.

In some aspects of the present disclosure, the instruction field contains two bits to signify whether the instruction is a read, write, shift-in, or shift-out instruction and the rest of the field specifies the application data register to be addressed. If the instruction bits are “00”, the slave test controller enters a write state 522, writing data to an ADR from the data command register.

If the bits are “01”, the slave test controller enters a read state 508, where the values in an ADR are read and transferred into the data command register control/data field. The read state is followed by a shift-out/transmit state 506 where the application data register value read into the data command register is written out to the test data control bus along with master test controller ID and a write instruction. The write instruction includes a corresponding application data register value in the master test controller. The slave test controller takes over the bus in the read state 508 and serially drives out the data command register values onto the test data control bus in the transmit or shift out state 506. This is followed by a release state 520 where the test control bus is released and the controller returns to the idle state 504. A write instruction would also include additional data. For a write instruction, the corresponding ADR is loaded with the control/data field of the data command register in the write state. After data command register values are written to the test data control bus by the slave test controller, the master test controller wakes up, receives the data, and shifts it into its respective data command register.

If the instructions bits are “10”, the slave test controller enter the ADR_OUT state 524 where the data stored in the corresponding application data register (ADR) is shifted out via the SO (shift out) output port to a test control register (e.g. a built in self test control register (see FIG. 1) if so desired. If the instruction bits are “11” the state machine enters ADR_IN state 526 where data from a test control register can be serially shifted in via SI (shift in) input port to the ADR. Although the preceding description was with respect to specific actions in response to bits 00, 01, 11, and 10, the actions could be performed in response to other bit combinations.

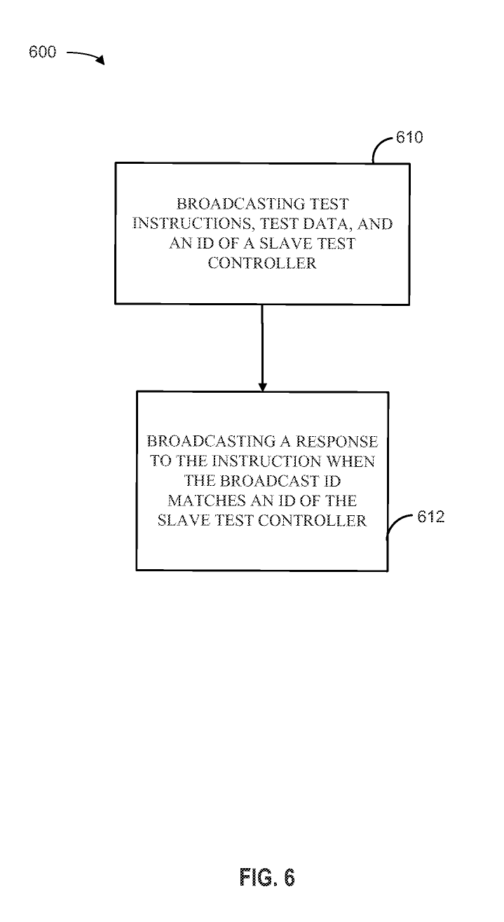

FIG. 6 illustrates a method 600 for broadcasting, recognizing and responding to test instructions. In block 610, a master test controller, within one of the components, and coupled to a test data and control bus (TDC) is configured to broadcast test instructions, test data, and an ID of a slave test controller. The slave test controller recognizes the broadcast test instructions and test data addressed to the slave test controller. In block 612, the slave test controller responds to the instruction when the broadcast ID matches an ID of the slave test controller. These methods may be carried out by the structures and components described above in relation to FIGS. 1, 2 and 4.

In one configuration, an apparatus has means for broadcasting, and means for broadcasting a response. In one aspect, the broadcasting means may be the finite state machine controller 214, configured to perform the functions recited by the broadcasting means via the TDC bus 212. The apparatus is also configured to include a means for broadcasting a response. In one aspect, the responding finite state machine controller 406, data command register 402, instruction register 414, and/or application data register 404 configured to perform the functions recited by the means for broadcasting a response via the TDC bus 408. In another aspect, the aforementioned means may be any module or any apparatus configured to perform the functions recited by the aforementioned means.

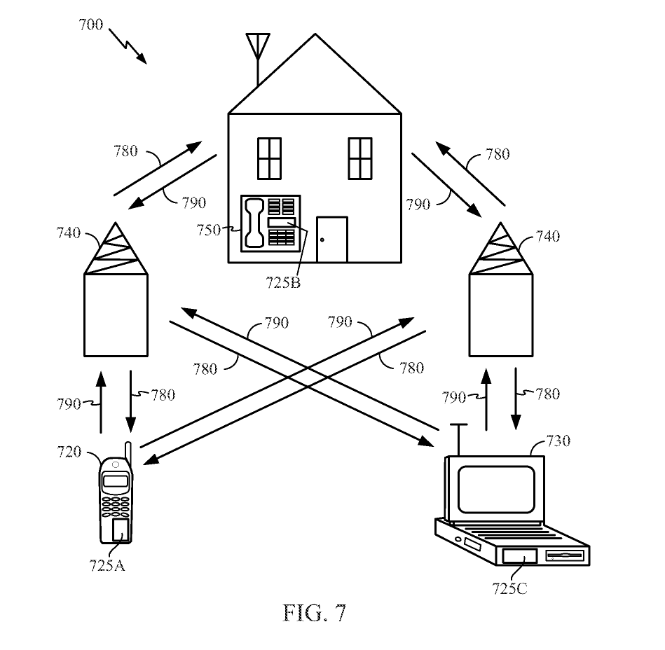

FIG. 7 shows an exemplary wireless communication system 700 in which a configuration of the disclosed testing method may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include multiple component testing circuitry 725A, 725B, and 725C, respectively. FIG. 7 shows forward link signals 780 from the base stations 740 and the remote units 720, 730, and 750 and reverse link signals 790 from the remote units 720, 730, and 750 to base stations 740.

In FIG. 7, the remote unit 720 is shown as a mobile telephone, remote unit 730 is shown as a portable computer, and remote unit 750 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 7 illustrates remote units, which may employ testing circuitry according to the teachings of the disclosure, the disclosure is not limited to these exemplary illustrated units. For instance, testing circuitry according to configurations of the present disclosure may be suitably employed in any device.

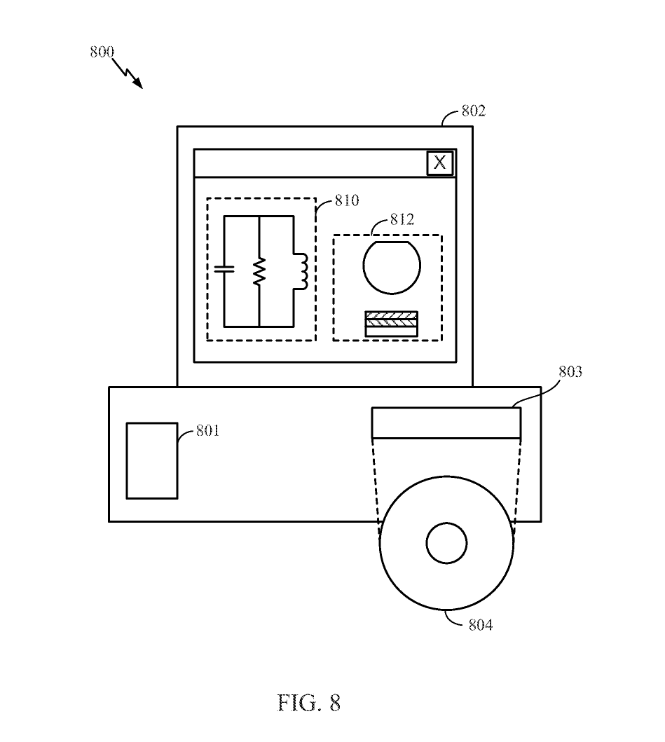

FIG. 8 is a block diagram illustrating a design workstation used for circuit, layout, and logic design of a semiconductor component, such as the testing circuitry disclosed above. A design workstation 800 includes a hard disk 801 containing operating system software, support files, and design software such as Cadence or OrCAD. The design workstation 800 also includes a display 802 to facilitate design of a circuit 810 or a semiconductor component 812 such as the testing circuitry. A storage medium 804 is provided for tangibly storing the circuit design 810 or the semiconductor component 812. The circuit design 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit design 810 or the semiconductor component 812 by decreasing the number of processes for designing semiconductor wafers.

Although specific circuitry has been set forth, it will be appreciated by those skilled in the art that not all of the disclosed circuitry is required to practice the disclosed configurations. Moreover, certain well known circuits have not been described, to maintain focus on the disclosure. Similarly, although the relative terms “upper” and “lower” are used, these terms are non-limiting. For example if a device is rotated by 90 degrees the terms “upper” and “lower” would refer to “left most” and “right most” portions.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the disclosure herein may be embodied directly in hardware, in a software module executed by a processor, or in a combination of the two.

The methodologies described herein may be implemented by various components depending upon the application. For example, these methodologies may be implemented in hardware, firmware, software, or any combination thereof For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus for testing a multiple component integrated circuit (IC), comprising:
a master test controller, within one of the components, and coupled to a test data control (TDC) bus and configured to broadcast test instructions, test data, and an ID of a slave test controller; and
at least one slave test controller, within another of the components, and coupled to the TDC bus, configured to recognize the broadcast test instructions and test data addressed to the slave test controller, and to respond to the instruction when the instruction is addressed to the slave test controller.

2. The apparatus of claim 1, in which the components comprise tiers of a 3D stacked IC.

3. The apparatus of claim 1, in which the components comprise cores of a multi core IC.

4. The apparatus of claim 1, in which the master test controller comprises an external data command register configured to receive the test instructions, test data, and ID of the slave test controller.

5. The apparatus of claim 4, in which the external data command register is configured to receive the test instructions, test data, and the ID of the slave test controller from at least one of a TAP (test access port) and a processor interface.

6. The apparatus of claim 4, in which the master test controller further comprises:
a data command register coupled to the external data command register;
a plurality of application data registers coupled to the data command register; and
a finite state machine controller coupled to the application data registers, data command register and the test data control bus.

7. The apparatus of claim 1, integrated into at least one of a mobile phone, a set top box, a music player, a video player, an entertainment unit, a navigation device, a computer, a hand-held personal communication systems (PCS) unit, a portable data unit, and a fixed location data unit.

8. A method of testing a multiple component integrated circuit (IC), comprising:
broadcasting test instructions, test data, and an ID of a slave test controller; and
broadcasting a response to the test instruction when the broadcast ID matches the ID of the slave test controller.

9. The method of claim 8, further comprises receiving the test instructions, test data and the ID of the slave test controller from an external testing device.

10. The method of claim 8, in which the components comprise tiers of a 3D stacked IC.

11. The method of claim 8, in which the components comprise cores of a multi core IC.

12. The method of claim 8, further comprising processing the response to determine when an ID in the response matches an ID of the master test controller.

13. The method of claim 12, further comprising storing data in the response to a designated application data register when the ID in the response matches.

14. The method of claim 8, further comprising integrating the IC into at least one of a mobile phone, a set top box, a music player, a video player, an entertainment unit, a navigation device, a computer, a hand-held personal communication systems (PCS) unit, a portable data unit, and a fixed location data unit.

15. An apparatus for testing a multiple component integrated circuit (IC), comprising:
means for broadcasting test instructions, test data, and an ID of a slave test controller, from a master test controller, within one of the components; and
means for broadcasting a response to the instruction when the broadcast ID matches an ID of the slave test controller.

16. The apparatus of claim 15, in which the test instruction broadcasting means comprises means for receiving the test instructions, test data, and ID of the slave test controller.

17. The apparatus of claim 16, in which the test instruction broadcasting means further comprises means for storing test data.

18. The apparatus of claim 15, in which the components compose tiers of a 3D stacked IC.

19. The apparatus of claim 15, in which the components compose cores of a multi core die.

20. The apparatus of claim 15, integrated into at least one of a mobile phone, a set top box, a music player, a video player, an entertainment unit, a navigation device, a computer, a hand-held personal communication systems (PCS) unit, a portable data unit, and a fixed location data unit.

21. A method of testing a multiple component integrated circuit (IC), comprising the steps of:
broadcasting test instructions, test data, and an ID of a slave test controller; and
broadcasting a response to the test instruction when the broadcast ID matches the ID of the slave test controller.

22. The method of claim 21, further comprising the step of integrating the IC into at least one of a mobile phone, a set top box, a music player, a video player, an entertainment unit, a navigation device, a computer, a hand-held personal communication systems (PCS) unit, a portable data unit, and a fixed location data unit.
